(19) United States
(12) Patent Application Publication
(10) Pub. No.: US 2014/0167739 A1
(43) Pub. Date: Jun. 19, 2014

(54) CURRENT DETECTING CIRCUIT BOARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: MIAO HE, Shenzhen (CN); JIAN-ZHI LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/093,061

(22) Filed: Nov. 29, 2013

(30) Foreign Application Priority Data
Dec. 14, 2012 (CN) 2012105437970

(51) Int. Cl. G01R 19/00

(52) U.S. Cl. CPC G01R 19/0092
USPC 324/126

(57) ABSTRACT

A circuit board with a current detecting circuit includes an inductor, two short pads, and an integrated chip. The inductor is connected between a first electronic component and a second electronic component. One of the short pads is in tight contact with a first pin of the inductor, and the other of the short pads is in tight contact with a second pin of the inductor. The integrated chip is connected to the first pin and the second pin of the inductor via the two short pads.

### BACKGROUND

1. Technical Field

The present disclosure relates to circuit boards, and particularly to a current detecting circuit board with a current detecting circuit board.

2. Description of Related Art

Current detecting circuits are commonly used to detect the current between two electronic components. The current detecting circuit usually includes an inductor connected between two electronic components, two short pads respectively connected to two pins of the inductor, and an integrated chip connected to the inductor via the two short pads to detect the current.

However, when designing the current detecting circuit board, the two short pads are usually placed far away from the inductor and the integrated chip, which is problematic when using a cable line to connect the short pads, the inductor, and the integrated chip together.

Therefore, it is desirable to provide a circuit board to overcome the above mentioned problem.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure. Moreover, in the drawings, like reference numerals designate corresponding units throughout the several views.

FIG. 1 is a circuit diagram of one embodiment of a circuit board with a current detecting circuit.

FIG. 2 is a layout diagram of the circuit board shown in FIG. 1.

### DETAILED DESCRIPTION

Embodiments of the present disclosure are described with reference to the accompanying drawings.

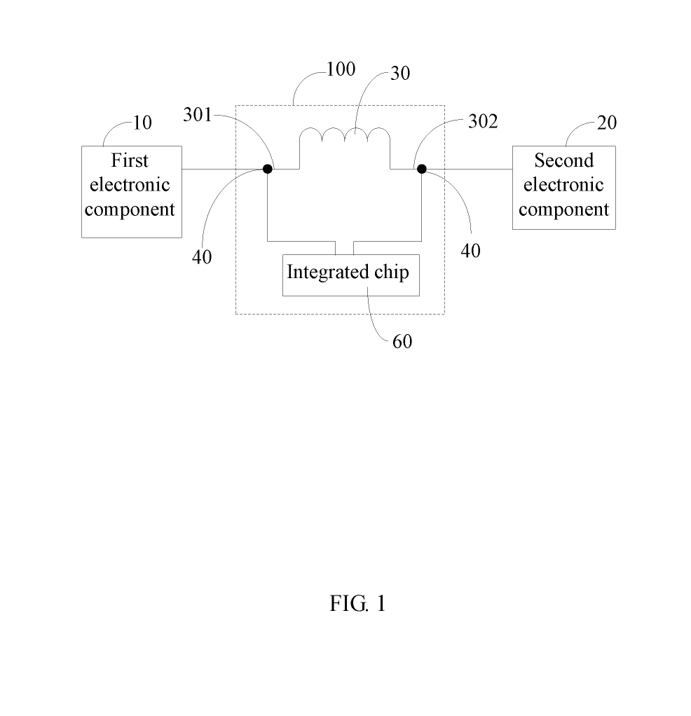

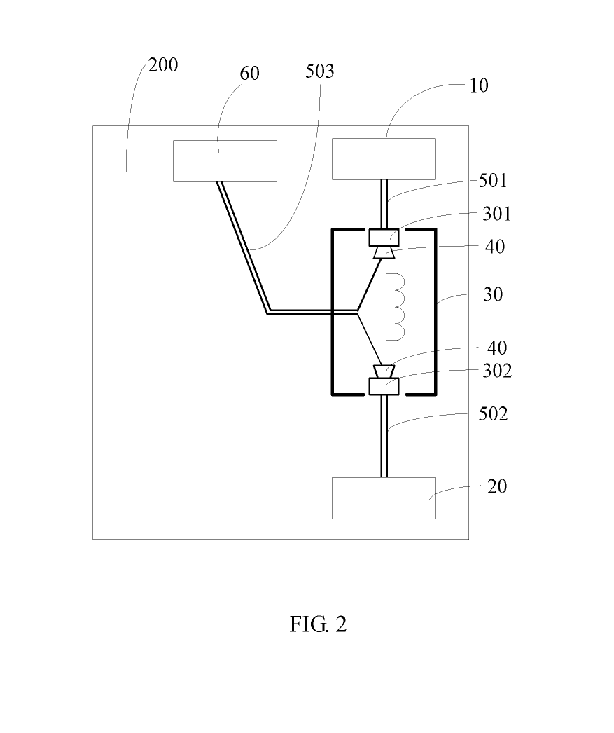

FIGS. 1-2 show an embodiment of a circuit board 200 with a current detecting circuit 100. The current detecting circuit 100 is used to detect a current between a first electronic component 10 and a second electronic component 20. The current detecting circuit 100 includes an inductor 30, two short pads 40, and an integrated chip 60. The inductor 30 includes a first pin 301 and a second pin 302. The first pin 301 is connected to the first electronic component 10 via a first cable line 501, and the second pin 302 is connected to the second electronic component 20 via a second cable line 502. The two short pads 40 are respectively connected to the first pin 301 and the second pin 302 of the inductor 30. One short pad 40 is in tight contact with one of the first pin 301 and the second pin 302 of the inductor 30, and the other short pad 40 is in tight contact with another of the first pin 301 and the second pin 302. The integrated chip 60 is connected to the first pin 301 and the second pin 302 of the inductor 30 via a third cable line 503 and the two short pads 40. The integrated chip 60 detects the current on the inductor 30 to determine the current between the first electronic component 10 and the second electronic component 20.

The above mentioned method allows the two short pads tightly contacted to the pins of the inductor, which overcomes the problem described in the background.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A circuit board with a current detecting circuit, the circuit board comprising:
an inductor comprising a first pin and a second pin, the first pin being connected to a first electronic component via a first cable line, the second pin being connected to a second electronic component via a second cable line;
two short pads respectively connected to the first pin and the second pin of the inductor, wherein one of the short pads is in tight contact with the first pin, and the other of the short pads is in tight contact with the second pin; and
an integrated chip connected to the first pin and the second pin of the inductor via a third cable line and the two short pads.

2. The circuit board as described in claim 1, wherein the first electronic component is a central processing unit, and the second electronic component is a power supply providing powers to the central processing unit.
